(19) United States
(12) Patent Application Publication
(10) Pub. No.: US 2026/0305353 A1
(43) Pub. Date: Oct. 1, 2026

(54) MEMORY DEVICES WITH REDUCED WARPAGE

(71) Applicant: SK hynix Inc., Icheon-si (KR)

(72) Inventor: Sung Lae OH, Icheon-si (KR)

(21) Appl. No.: 19/308,088

(22) Filed: Aug. 22, 2025

(30) Foreign Application Priority Data
Mar. 25, 2025 (KR) 10-2025-0038065

(51) Int. Cl. H01L 23/00; H10B 43/35

(52) U.S. Cl. CPC H10W 42/121; H10B 43/35

(57) ABSTRACT

A memory device according to embodiments of the present disclosure may include a stack including a plurality of electrode layers and a plurality of interlayer insulating layers that are alternately stacked in a vertical direction; a source plate disposed on the stack; and a plurality of warpage prevention patterns disposed on the source plate.

### CROSS-REFERENCE TO RELATED APPLICATION

The present application claims priority under 35 U.S.C. § 119(a) to Korean Patent Application No. 10-2025-0038065 filed in the Korean Intellectual Property Office on Mar. 25, 2025, which is incorporated herein by reference in its entirety.

### BACKGROUND

### 1. Technical Field

Embodiments of the present disclosure relate to a memory device.

### 2. Related Art

Memory devices with two-dimensional or planar structures have been developed to be able to store more data within the same area by using fine patterning processes as compared to conventional devices. However, with increasingly narrow circuit line widths due to demands for high integration, interference between memory cells worsens, resulting in various limitations such as deterioration in performance. Of course, in addition to these structural limitations, there is also a problem because expensive equipment is needed to pattern fine line widths, which inevitably increases fabricating costs.

Three-dimensional memory devices have been proposed as an alternative to overcome the limitations of two-dimensional memory devices. The three-dimensional memory devices have advantages in that larger capacity may be realized within the same area by increasing the number of stacks through stacking memory cells in a vertical direction, thereby providing high performance and excellent power efficiency.

Warpage may occur in a memory device due to the inherent stresses of material layers used in the memory device and the stresses induced during the material layer deposition process and the heat treatment process of the memory device.

### SUMMARY

Embodiments of the present disclosure are directed to providing a memory device capable of suppressing occurrence of warpage.

Objects of embodiments of the disclosure are not limited to those set forth herein, and other objects not mentioned here will be apparent to one of ordinary skill in the art from the following description.

In an embodiment, a memory device may include: a stack including a plurality of electrode layers and a plurality of interlayer insulating layers that are alternately stacked in a vertical direction; a source plate disposed on the stack; and a plurality of warpage prevention patterns disposed on the source plate.

In an embodiment, a memory device may include: a first stack disposed in a first plane region, and including a plurality of first electrode layers and a plurality of first interlayer insulating layers that are alternately stacked in a vertical direction; a second stack disposed in a second plane region, and including a plurality of second electrode layers and a plurality of second interlayer insulating layers that are alternately stacked in the vertical direction; a first source plate disposed on the first stack; a second source plate disposed on the second stack; a plurality of first warpage prevention patterns disposed on the first source plate; and a plurality of second warpage prevention patterns disposed on the second source plate.

In an embodiment, a memory device may include: a lower structure; and an upper structure disposed on the lower structure, wherein the lower structure includes: a lower stack including a plurality of lower electrode layers and a plurality of lower interlayer insulating layers that are alternately stacked in a vertical direction; a lower source plate disposed on the lower stack; and a plurality of lower warpage prevention patterns disposed on the lower source plate, and wherein the upper structure includes: an upper stack including a plurality of upper electrode layers and a plurality of upper interlayer insulating layers that are alternately stacked in the vertical direction; an upper source plate disposed on the upper stack; and a plurality of upper warpage prevention patterns disposed on the upper source plate.

In an embodiment, a memory device may include: a lower structure; and an upper structure disposed on the lower structure, wherein the lower structure includes: a first lower stack including a plurality of first lower electrode layers and a plurality of first lower interlayer insulating layers that are alternately stacked in a vertical direction in a first plane region; a second lower stack including a plurality of second lower electrode layers and a plurality of second lower interlayer insulating layers that are alternately stacked in the vertical direction in a second plane region neighboring the first plane region in a horizontal direction; a first lower source plate disposed on the first lower stack; a second lower source plate disposed on the second lower stack; a plurality of first lower warpage prevention patterns disposed on the first lower source plate; and a plurality of second lower warpage prevention patterns disposed on the second lower source plate, and wherein the upper structure includes: a first upper stack including a plurality of first upper electrode layers and a plurality of first upper interlayer insulating layers that are alternately stacked in the vertical direction in the first plane region; a second upper stack including a plurality of second upper electrode layers and a plurality of second upper interlayer insulating layers that are alternately stacked in the vertical direction in the second plane region; a first upper source plate disposed on the first upper stack; a second upper source plate disposed on the second upper stack; a plurality of first upper warpage prevention patterns disposed on the first upper source plate; and a plurality of second upper warpage prevention patterns disposed on the second upper source plate.

According to embodiments of the present disclosure, it is possible to provide a memory device capable of suppressing occurrence of warpage.

The effects of the disclosure are not limited to the foregoing objects, and other effects will be apparent to one of ordinary skill in the art from the following detailed description.

### BRIEF DESCRIPTION OF THE DRAWINGS

The disclosure will be more fully understood from the following detailed description and the accompanying drawings, which are provided for illustration only and are not intended to limit the disclosure.

FIG. 1 to FIG. 3 are cross-sectional views of memory devices according to embodiments of the present disclosure.

FIG. 4 to FIG. 6 are plan views schematically illustrating warpage prevention patterns of memory devices according to embodiments of the present disclosure.

FIG. 7 is a plan view illustrating regions of a memory device according to an embodiment of the present disclosure.

FIG. 8 and FIG. 9 are cross-sectional views of the memory device according to embodiments of the present disclosure.

FIG. 10 to FIG. 13 are plan views schematically illustrating warpage prevention patterns of memory devices according to embodiments of the present disclosure.

FIG. 14 to FIG. 17 are cross-sectional views of memory devices according to embodiments of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element in between.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

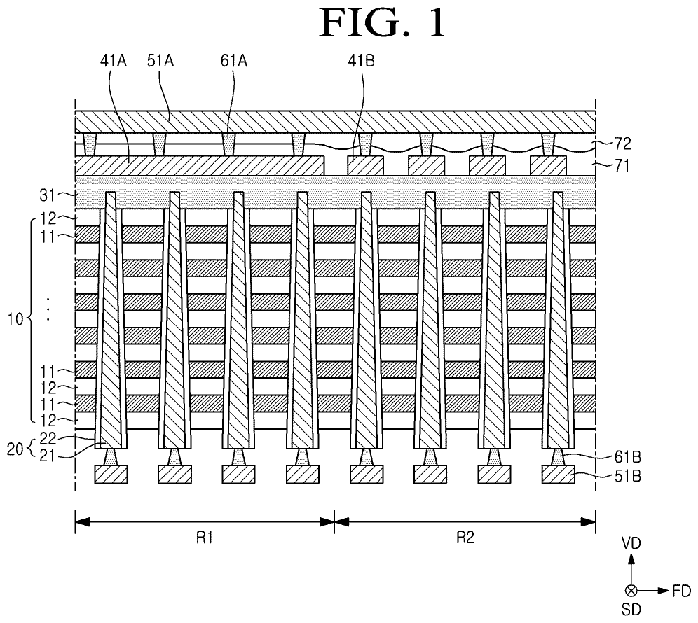

FIG. 1 is a cross-sectional view illustrating a part of a memory device according to an embodiment of the present disclosure.

Referring to FIG. 1, a memory device according to an embodiment of the present disclosure may include a stack 10, a cell plug 20, a source plate 31, and a plurality of warpage prevention patterns 41A and 41B.

The stack 10 may include a plurality of electrode layers 11 and a plurality of interlayer insulating layers 12 that are alternately stacked in a vertical direction VD.

The electrode layers 11 may extend in a first horizontal direction FD. The electrode layers 11 may constitute row lines. The row lines may include at least one source select line, a plurality of word lines and a plurality of drain select lines. At least one from the top among the electrode layers 11 may constitute a source select line. At least one from the bottom among the electrode layers 11 may constitute a drain select line. Electrode layers 11 between the source select line and the drain select line may constitute word lines.

The electrode layers 11 may include at least one selected among doped semiconductor, metal, conductive metal nitride or transition metal. The doped semiconductor may include doped silicon. The metal may include at least one selected among tungsten, copper or aluminum. The conductive metal nitride may include at least one selected among titanium nitride or tantalum nitride. The transition metal may include at least one selected among titanium or tantalum. The interlayer insulating layers 12 may include silicon oxide.

The cell plug 20 may penetrate the stack 10 in the vertical direction VD. The cell plug 20 may include a cell channel layer 21 and a cell gate insulating layer 22. The cell channel layer 21 may be formed of a semiconductor material. The cell channel layer 21 may include silicon. The upper end of the cell channel layer 21 may protrude out of the upper surface of the stack 10.

The cell gate insulating layer 22 may have a straw or cylinder shell shape that surrounds the outer wall of the cell channel layer 21. The cell gate insulating layer 22 may include a tunnel insulating layer, a charge storage layer and a blocking layer that are sequentially stacked from the outer sidewall of the cell channel layer 21. In some embodiments, the cell gate insulating layer 22 may have an ONO (oxide-nitride-oxide) stack structure in which an oxide layer, a nitride layer and an oxide layer are sequentially stacked. The upper end of the cell channel layer 21 protruding out of the upper surface of the stack 10 might not be covered with the cell gate insulating layer 22.

A source select transistor may be formed in an area where a source select line surrounds the cell plug 20. Memory cells may be formed in areas where word lines surround the cell plug 20. A drain select transistor may be formed in an area where a drain select line surrounds the cell plug 20. A source select transistor, a plurality of memory cells and a drain select transistor that are disposed along one cell plug 20 may constitute one cell string.

A plurality of cell plugs 20 may penetrate the stack 10 in the vertical direction VD. A plurality of cell strings corresponding to the plurality of cell plugs 20 may be defined. The plurality of cell strings may constitute a memory cell array. Although embodiments to be described with reference to the drawings illustrate a case where a memory cell is a NAND cell, the type of a memory cell is not limited thereto. A memory cell may be a DRAM cell or a resistive cell.

The source plate 31 may be disposed on the stack 10. The source plate 31 may surround the upper end of the cell channel layer 21 that protrudes out of the stack 10. The source plate 31 may be connected to the cell channel layer 21.

The warpage prevention patterns 41A and 41B may be disposed on the source plate 31. The warpage prevention patterns 41A and 41B may be provided to disperse or alleviate stress so as to suppress warpage. The warpage prevention patterns 41A and 41B may have material with a hardness greater than the hardness of the source plate 31.

The warpage prevention patterns 41A and 41B may be connected to the source plate 31. The warpage prevention patterns 41A and 41B may contact the upper surface of the source plate 31. The warpage prevention patterns 41A and 41B may transmit a source voltage to the source plate 31. The warpage prevention patterns 41A and 41B may be formed of a conductive material with a lower resistivity than the source plate 31. For example, the source plate 31 may include polysilicon, and the warpage prevention patterns 41A and 41B may include metal.

Because the source voltage is supplied to the source plate 31 through the plurality of warpage prevention patterns 41A and 41B disposed on the upper surface of the source plate 31, area-specific deviation in the source voltage of the source plate 31 may be reduced, thereby reducing source bouncing. Accordingly, the threshold voltage distribution of memory cells may be reduced, programming speed may be increased, and operation characteristics may be improved.

The memory device may have a first region R1 and a second region R2 that neighbors the first region R1. The extending direction of the warpage prevention patterns 41A disposed in the first region R1 and the extending direction of the warpage prevention patterns 41B disposed in the second region R2 may be different from each other. As illustrated in FIG. 1, the warpage prevention patterns 41A of the first region R1 may extend in the first horizontal direction FD, and the warpage prevention patterns 41B of the second region R2 may extend in a second horizontal direction SD. Although only one warpage prevention pattern 41A is illustrated in the first region R1 in FIG. 1, a plurality of warpage prevention patterns 41A may be arranged in the second horizontal direction SD. The warpage prevention patterns 41B of the second region R2 may be arranged in the first horizontal direction FD.

As illustrated in FIG. 1, the first horizontal direction FD and the second horizontal direction SD may represent two directions that intersect each other perpendicularly, but other embodiments are not limited thereto. The first horizontal direction FD and the second horizontal direction SD may be two directions that intersect each other while forming an angle other than a right angle.

Because the warpage prevention patterns 41A of the first region R1 and the warpage prevention patterns 41B of the second region R2 do not extend in the same direction but in different directions, stress may be suppressed from being concentrated in one direction, and occurrence of warpage by stress concentration may be suppressed.

A first insulating layer 71 may be defined on the source plate 31 to cover the warpage prevention patterns 41A and 41B. The first insulating layer 71 may have protrusions corresponding to the warpage prevention patterns 41A and 41B on the upper surface thereof. The protrusions may extend in the extending directions of the warpage prevention patterns 41A and 41B, and may be arranged in the arrangement directions of the warpage prevention patterns 41A and 41B. For example, in the first region R1, the protrusions of the first insulating layer 71 may extend in the first horizontal direction FD and be arranged in the second horizontal direction SD. In the second region R2, the protrusions of the first insulating layer 71 may extend in the second horizontal direction SD and be arranged in the first horizontal direction FD.

A second insulating layer 72 may be disposed on the first insulating layer 71, and a source line 51A may be disposed on the second insulating layer 72. The source line 51A may be connected to the warpage prevention patterns 41A and 41B through a plurality of vias 61A. The source line 51A may be connected to the source plate 31 through the vias 61A and the warpage prevention patterns 41A and 41B. The source voltage loaded on the source line 51A may be transmitted to the source plate 31 through the vias 61A and the warpage prevention patterns 41A and 41B.

Bit lines 51B may be disposed under the stack 10. The bit lines 51B may extend in the second horizontal direction SD and be arranged in the first horizontal direction FD. A bit line 51B may be connected to a cell plug 20 through a via 61B.

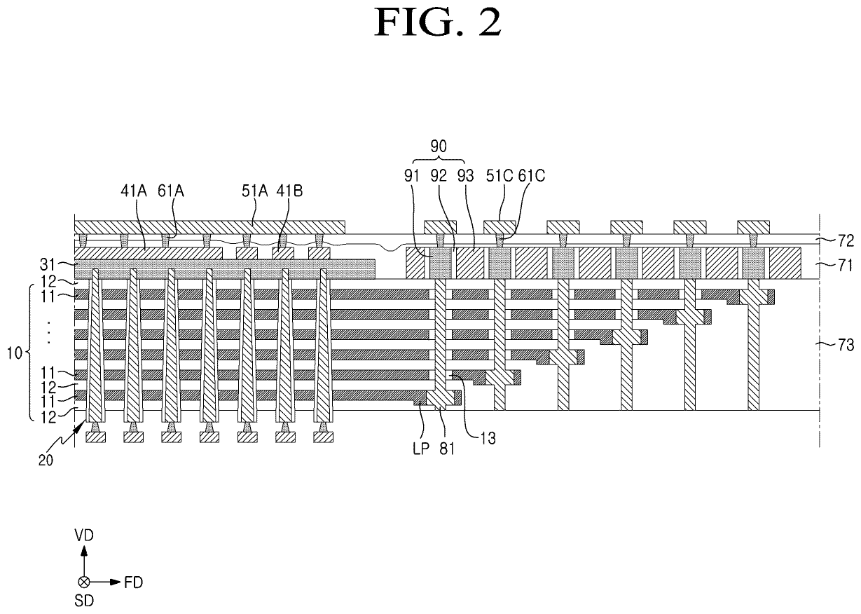

FIG. 2 is a cross-sectional view illustrating a part of a memory device according to an embodiment of the present disclosure. Hereinbelow, duplicate descriptions of components that are the same as those of FIG. 1 will be omitted.

Referring to FIG. 2, a stack 10 may have a stairway structure. Each of electrode layers 11 may have a pad area LP. The pad area LP of an upper electrode layer 11 may protrude more than an lower electrode layer 11 in the first horizontal direction FD. The pad areas LP of successive electrode layers 11 are staggered to result in step-like shapes to form a stairway structure. The pad area LP may be thicker than the other portion of the electrode layer 11.

A contact 81 may penetrate the stack 10 in the vertical direction VD and be connected to a corresponding electrode layer 11. The contact 81 may penetrate the pad area LP of the corresponding electrode layer 11. The upper end of the contact 81 may be exposed at the upper surface of the stack 10.

Insulating patterns 13 may be disposed between the contact 81 and other electrode layers 11, other than the corresponding electrode layer 11. The insulating patterns 13 may isolate the contact 81 and the other electrode layers 11. Each insulating pattern 13 may be disposed in the vertical direction VD between two neighboring interlayer insulating layers 12 among the plurality of interlayer insulating layers 12. The insulating patterns 13 may be formed of an insulating material that has an etching selectivity different from that of the interlayer insulating layers 12. For example, the interlayer insulating layers 12 may be formed of oxide, and the insulating patterns 13 may be formed of nitride.

A source plate 31 may be disposed on the stack 10. The source plate 31 may be designed to expose contacts 81 and the stack 10 around the contacts 81.

A plurality of pass transistors 90 may be disposed on the stack 10. Each pass transistor 90 may include a semiconductor pillar 91, a gate insulating layer 92 and a gate electrode 93.

The semiconductor pillar 91 may extend in the vertical direction VD on the contact 81. The semiconductor pillar 91 may be connected to the contact 81. The semiconductor pillar 91 may contact the upper end of the contact 81. The semiconductor pillar 91 may be connected to a corresponding electrode layer 11 through the contact 81.

The semiconductor pillar 91 may be formed of a semiconductor material. The semiconductor material may include monocrystalline silicon. The channel of the pass transistor 90 may be formed in the semiconductor pillar 91. The channel of the pass transistor 90 may extend in the vertical direction VD, which is the extending direction of the semiconductor pillar 91.

The gate insulating layer 92 may surround the outer wall of the semiconductor pillar 91. The gate insulating layer 92 may have a straw or cylinder shell shape.

The gate electrode 93 may surround the outer wall of the gate insulating layer 92. The gate electrode 93 may surround the outer walls of the gate insulating layers 92 of the plurality of pass transistors 90. One gate electrode 93 may be shared by the plurality of pass transistors 90. The height of the gate electrode 93 may be substantially the same as the height of the semiconductor pillar 91. The gate electrode 93 may have a thickness thicker than the thickness of the source plate 31.

The pass transistor 90 may transmit an operating voltage to the electrode layer 11. Operating voltages may include a program voltage (Vpgm), an unselected read voltage (Vread), a read voltage (Vrd), a pass voltage (Vpass) and a verify voltage (Vfy). The unselected read voltage (Vread) is a voltage that is provided to an unselected word line during a read operation. The read voltage (Vrd) is a voltage that is provided to a selected word line during the read operation. The program voltage (Vpgm), the pass voltage (Vpass) or the unselected read voltage (Vread) corresponds to a high voltage. The pass transistor 90 is a high-voltage transistor, and the channel of the pass transistor 90 should have a length longer than the channel of a low-voltage transistor to withstand a high voltage. Because the channel of the pass transistor 90 extends in the vertical direction VD, which is the extending direction of the semiconductor pillar 91, the height of the semiconductor pillar 91 may be increased to implement a pass transistor 90 with a long channel length.

A first insulating layer 71 may be defined on the stack 10 to cover the source plate 31, warpage prevention patterns 41A and 41B and the pass transistors 90. A second insulating layer 72 may be disposed on the first insulating layer 71. A global row line 51C may be disposed on the second insulating layer 72. The global row line 51C may be connected to the semiconductor pillar 91 of the pass transistor 90 through a via 61C. The global row line 51C may be connected to a voltage generator (not illustrated) and may transmit an operating voltage provided from the voltage generator to the pass transistor 90.

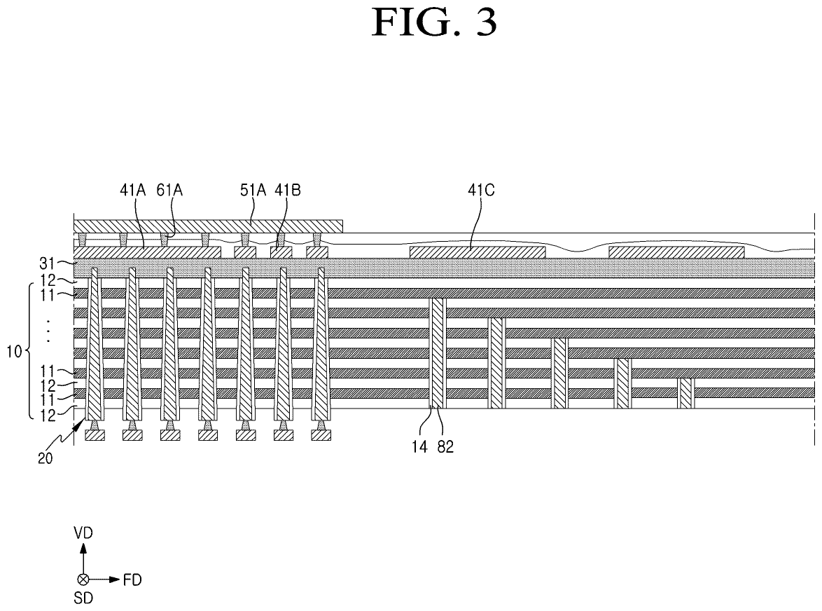

FIG. 3 is a cross-sectional view illustrating a part of a memory device according to an embodiment of the present disclosure. Hereinbelow, duplicate descriptions of components that are the same as those of FIG. 1 will be omitted.

Referring to FIG. 3, a contact 82 may extend from the lower surface of a stack 10 through the stack 10 in the vertical direction VD to a corresponding electrode layer 11. The upper end of the contact 82 may be connected to a corresponding electrode layer 11. The upper end of the contact 82 is not exposed at the upper surface of the stack 10. An insulating spacer 14 may be disposed on the side surface of the contact 82. The insulating spacer 14 may have a straw or cylinder shell shape that surrounds the side surface of the contact 82. The insulating spacer 14 may isolate the side surface of the contact 82 and the other electrode layers 11.

A source plate 31 may be disposed on the stack 10. The source plate 31 may overlap the contact 82 in the vertical direction VD. Warpage prevention patterns 41A, 41B and 41C may be disposed on the source plate 31. A warpage prevention pattern 41C may be disposed over one or more contacts 82.

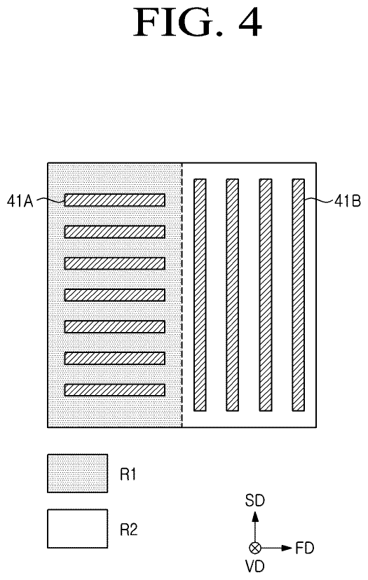

FIG. 4 to FIG. 6 are plan views schematically illustrating warpage prevention patterns of memory devices according to embodiments of the present disclosure.

Referring to FIG. 4, a memory device according to an embodiment of the present disclosure may have a first region R1 and a second region R2 that neighbor each other in the first horizontal direction FD.

The extending direction of warpage prevention patterns 41A disposed in the first region R1 and the extending direction of warpage prevention patterns 41B disposed in the second region R2 may be different from each other. As illustrated in FIG. 4, the warpage prevention patterns 41A disposed in the first region R1 may extend in the first horizontal direction FD, and the warpage prevention patterns 41B disposed in the second region R2 may extend in the second horizontal direction SD. In FIG. 4, the memory device has one first region R1 and one second region R2 that are adjacent in the first horizontal direction FD, but the present disclosure is not limited thereto. Although not illustrated, the memory device may have a plurality of first regions and a plurality of second regions that are alternately disposed in the first horizontal direction FD.

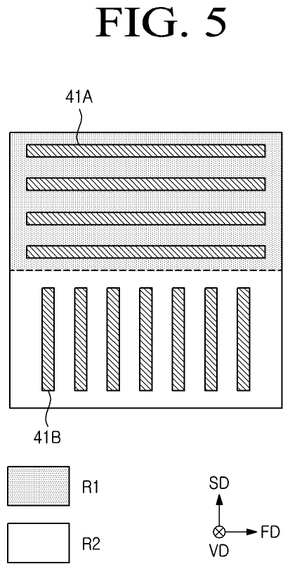

Referring to FIG. 5, a memory device according to an embodiment of the present disclosure may have a first region R1 and a second region R2 that neighbor each other in the second horizontal direction SD.

The extending direction of warpage prevention patterns 41A disposed in the first region R1 and the extending direction of warpage prevention patterns 41B disposed in the second region R2 may be different from each other. As illustrated in FIG. 5, the warpage prevention patterns 41A disposed in the first region R1 may extend in the first horizontal direction FD, and the warpage prevention patterns 41B disposed in the second region R2 may extend in the second horizontal direction SD. In FIG. 5, the memory device has one first region R1 and one second region R2 that are adjacent in the second horizontal direction SD, but the present disclosure is not limited thereto. Although not illustrated, the memory device may have a plurality of first regions and a plurality of second regions that are alternately disposed in the second horizontal direction SD.

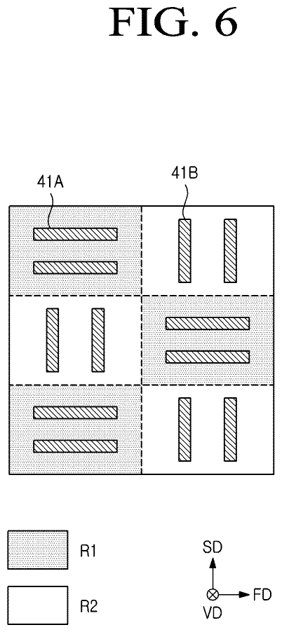

Referring to FIG. 6, a memory device according to an embodiment of the present disclosure may include a plurality of first regions R1 and a plurality of second regions R2 that are alternately disposed in the first horizontal direction FD and the second horizontal direction SD.

The extending direction of warpage prevention patterns 41A disposed in the first regions R1 and the extending direction of warpage prevention patterns 41B disposed in the second regions R2 may be different from each other. As illustrated in FIG. 6, the warpage prevention patterns 41A disposed in the first regions R1 may extend in the first horizontal direction FD, and the warpage prevention patterns 41B disposed in the second regions R2 may extend in the second horizontal direction SD. In FIG. 6, three first regions R1 and three second regions R2 are disposed alternately in the first horizontal direction FD and the second horizontal direction SD, but the present disclosure is not limited thereto. Two or more first regions and two or more second regions may be disposed alternately in the first horizontal direction FD and the second horizontal direction SD to form a checkerboard pattern.

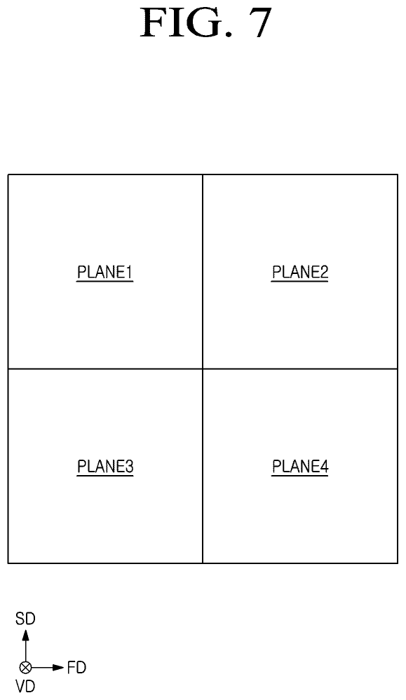

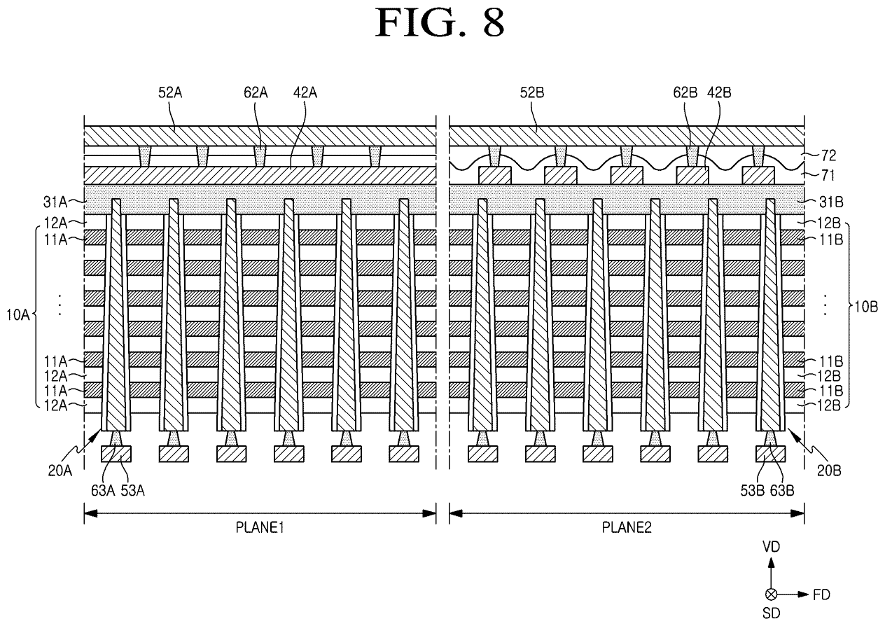

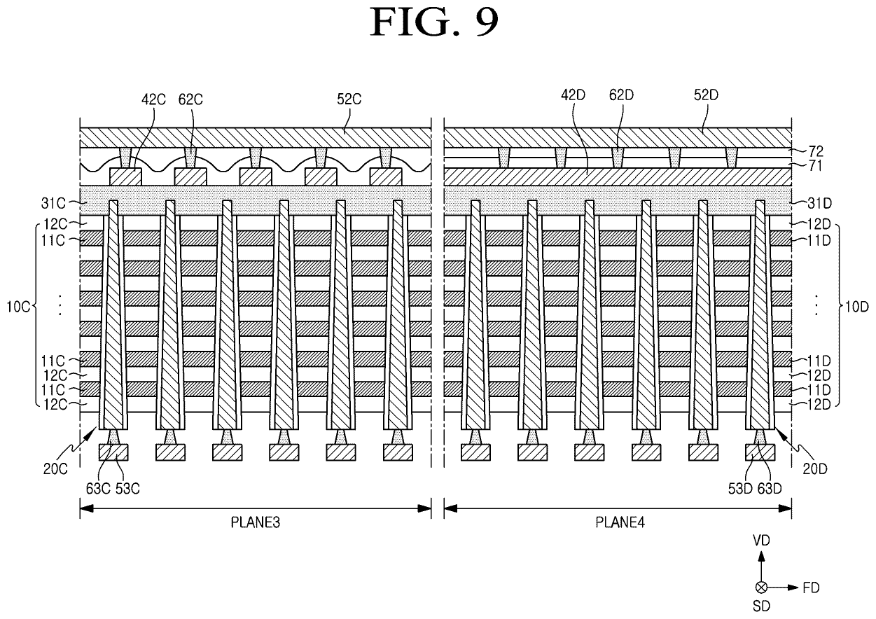

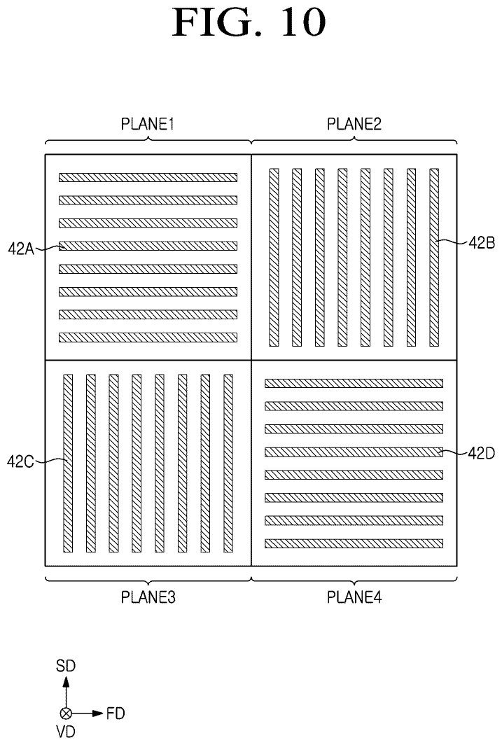

FIG. 7 is a plan view illustrating regions of a memory device according to an embodiment of the present disclosure, FIG. 8 and FIG. 9 are cross-sectional views of the memory device according to embodiments of the present disclosure, and FIG. 10 is a plan view schematically illustrating warpage prevention patterns of a memory device according to an embodiment of the present disclosure.

Referring to FIG. 7, a memory device according to an embodiment of the present disclosure may include first, second, third and fourth plane regions PLANE1, PLANE2, PLANE3 and PLANE4.

The first plane region PLANE1 and the second plane region PLANE2 may neighbor each other in the first horizontal direction FD, and the third plane region PLANE3 and the fourth plane region PLANE4 may neighbor each other in the first horizontal direction FD. The first plane region PLANE1 and the third plane region PLANE3 may be adjacent to each other in the second horizontal direction SD, and the second plane region PLANE2 and the fourth plane region PLANE4 may be adjacent to each other in the second horizontal direction SD. FIG. 7 illustrates a four-plane structure, but the present disclosure is not limited thereto. A memory device may include at least two planes.

Referring to FIG. 7 and FIG. 8, a first stack 10A, a first cell plug 20A, a first source plate 31A and first warpage prevention patterns 42A may be disposed in the first plane region PLANE1.

The first stack 10A may include a plurality of first electrode layers 11A and a plurality of first interlayer insulating layers 12A that are alternately stacked in the vertical direction VD.

The first cell plug 20A may penetrate the first stack 10A in the vertical direction VD. An upper end of the first cell plug 20A may protrude out of the upper surface of the first stack 10A. A plurality of first cell plugs 20A may penetrate the first stack 10A in the vertical direction VD. A plurality of first cell strings corresponding to the plurality of first cell plugs 20A may be defined. The plurality of first cell strings may constitute a first memory cell array.

The first source plate 31A may be disposed on the first stack 10A. The first source plate 31A may be connected to the upper end of the first cell plug 20A.

The first warpage prevention patterns 42A may be disposed on the first source plate 31A. The first warpage prevention patterns 42A may be provided to disperse or alleviate stress so as to suppress warpage of the device relative to a plane defined by the first direction FD and the second direction SD. The first warpage prevention patterns 42A may have a hardness greater than the hardness of the first source plate 31A.

The first warpage prevention patterns 42A may be connected to the first source plate 31A. The first warpage prevention patterns 42A may contact an upper surface of the first source plate 31A. The first warpage prevention patterns 42A may transmit a source voltage to the first source plate 31A. The first warpage prevention patterns 42A may have a resistivity lower than the resistivity of the first source plate 31A. The first source plate 31A may include polysilicon, and the first warpage prevention patterns 42A may include metal.

A second stack 10B, a second cell plug 20B, a second source plate 31B and second warpage prevention patterns 42B may be disposed in the second plane region PLANE2.

The second stack 10B may include a plurality of second electrode layers 11B and a plurality of second interlayer insulating layers 12B that are alternately stacked in the vertical direction VD.

The second cell plug 20B may penetrate the second stack 10B in the vertical direction VD. An upper end of the second cell plug 20B may protrude out of the upper surface of the second stack 10B. A plurality of second cell plugs 20B may penetrate the second stack 10B in the vertical direction VD. A plurality of second cell strings corresponding to the plurality of second cell plugs 20B may be defined. The plurality of second cell strings may constitute a second memory cell array.

The second source plate 31B may be disposed on the second stack 10B. The second source plate 31B may be connected to the upper end of the second cell plug 20B.

The second warpage prevention patterns 42B may be disposed on the second source plate 31B. The second warpage prevention patterns 42B may be provided to disperse or alleviate stress so as to suppress warpage of the device relative to a plane defined by the first direction FD and the second direction SD. The second warpage prevention patterns 42B may have a hardness greater than the hardness of the second source plate 31B.

The second warpage prevention patterns 42B may be connected to the second source plate 31B. The second warpage prevention patterns 42B may contact the upper surface of the second source plate 31B. The second warpage prevention patterns 42B may transmit a source voltage to the second source plate 31B. The second warpage prevention patterns 42B may have a resistivity lower than the resistivity of the second source plate 31B. The second source plate 31B may include polysilicon, and the second warpage prevention patterns 42B may include metal.

Referring to FIG. 7 and FIG. 9, a third stack 10C, a third cell plug 20C, a third source plate 31C and third warpage prevention patterns 42C may be disposed in the third plane region PLANE3.

The third stack 10C may include a plurality of third electrode layers 11C and a plurality of third interlayer insulating layers 12C that are alternately stacked in the vertical direction VD.

The third cell plug 20C may penetrate the third stack 10C in the vertical direction VD. An upper end of the third cell plug 20C may protrude out of the upper surface of the third stack 10C. A plurality of third cell plugs 20C may penetrate the third stack 10C in the vertical direction VD. A plurality of third cell strings corresponding to the plurality of third cell plugs 20C may be defined. The plurality of third cell strings may constitute a third memory cell array.

The third source plate 31C may be disposed on the third stack 10C. The third source plate 31C may be connected to the upper end of the third cell plug 20C.

The third warpage prevention patterns 42C may be disposed on the third source plate 31C. The third warpage prevention patterns 42C may be provided to disperse or alleviate stress so as to suppress warpage of the device relative to a plane defined by the first direction FD and the second direction SD. The third warpage prevention patterns 42C may have a hardness greater than the hardness of the third source plate 31C.

The third warpage prevention patterns 42C may be connected to the third source plate 31C. The third warpage prevention patterns 42C may contact the upper surface of the third source plate 31C. The third warpage prevention patterns 42C may transmit a source voltage to the third source plate 31C. The third warpage prevention patterns 42C may have a resistivity lower than the resistivity of the third source plate 31C. The third source plate 31C may include polysilicon, and the third warpage prevention patterns 42C may include metal.

A fourth stack 10D, a fourth cell plug 20D, a fourth source plate 31D and fourth warpage prevention patterns 42D may be disposed in the fourth plane region PLANE4.

The fourth stack 10D may include a plurality of fourth electrode layers 11D and a plurality of fourth interlayer insulating layers 12D that are alternately stacked in the vertical direction VD.

The fourth cell plug 20D may penetrate the fourth stack 10D in the vertical direction VD. An upper end of the fourth cell plug 20D may protrude out of the upper surface of the fourth stack 10D. A plurality of fourth cell plugs 20D may penetrate the fourth stack 10D in the vertical direction VD. A plurality of fourth cell strings corresponding to the plurality of fourth cell plugs 20D may be defined. The plurality of fourth cell strings may constitute a fourth memory cell array.

The fourth source plate 31D may be disposed on the fourth stack 10D. The fourth source plate 31D may be connected to the upper end of the fourth cell plug 20D.

The fourth warpage prevention patterns 42D may be disposed on the fourth source plate 31D. The fourth warpage prevention patterns 42D may be provided to disperse or alleviate stress so as to suppress warpage of the device relative to a plane defined by the first direction FD and the second direction SD. The fourth warpage prevention patterns 42D may have a hardness greater than the hardness of the fourth source plate 31D.

The fourth warpage prevention patterns 42D may be connected to the fourth source plate 31D. The fourth warpage prevention patterns 42D may contact the upper surface of the fourth source plate 31D. The fourth warpage prevention patterns 42D may transmit a source voltage to the fourth source plate 31D. The fourth warpage prevention patterns 42D may have a resistivity lower than the resistivity of the fourth source plate 31D. The fourth source plate 31D may include polysilicon, and the fourth warpage prevention patterns 42D may include metal.

A first insulating layer 71 may be disposed on the first, second, third and fourth source plates 31A, 31B, 31C and 31D to cover the first, second, third and fourth warpage prevention patterns 42A, 42B, 42C and 42D. The first insulating layer 71 may have protrusions corresponding to the first, second, third and fourth warpage prevention patterns 42A, 42B, 42C and 42D on the upper surface thereof.

A second insulating layer 72 may be disposed on the first insulating layer 71, and first, second, third and fourth source lines 52A, 52B, 52C and 52D may be disposed on the second insulating layer 72.

The first source line 52A may be disposed in the first plane region PLANE1. The first source line 52A may be connected to the first warpage prevention patterns 42A through a plurality of vias 62A. The first source line 52A may be connected to the first source plate 31A through the vias 62A and the first warpage prevention patterns 42A. The source voltage loaded on the first source line 52A may be transmitted to the first source plate 31A through the vias 62A and the first warpage prevention patterns 42A.

The second source line 52B may be disposed in the second plane region PLANE2. The second source line 52B may be connected to the second warpage prevention patterns 42B through a plurality of vias 62B. The second source line 52B may be connected to the second source plate 31B through the vias 62B and the second warpage prevention patterns 42B. The source voltage loaded on the second source line 52B may be transmitted to the second source plate 31B through the vias 62B and the second warpage prevention patterns 42B.

The third source line 52C may be disposed in the third plane region PLANE3. The third source line 52C may be connected to the third warpage prevention patterns 42C through a plurality of vias 62C. The third source line 52C may be connected to the third source plate 31C through the vias 62C and the third warpage prevention patterns 42C. The source voltage loaded on the third source line 52C may be transmitted to the third source plate 31C through the vias 62C and the third warpage prevention patterns 42C.

The fourth source line 52D may be disposed in the fourth plane region PLANE4. The fourth source line 52D may be connected to the fourth warpage prevention patterns 42D through a plurality of vias 62D. The fourth source line 52D may be connected to the fourth source plate 31D through the vias 62D and the fourth warpage prevention patterns 42D. The source voltage loaded on the fourth source line 52D may be transmitted to the fourth source plate 31D through the vias 62D and the fourth warpage prevention patterns 42D.

First bit lines 53A may be disposed under the first stack 10A. The first bit lines 53A may extend in the second horizontal direction SD and be arranged in the first horizontal direction FD. The first bit line 53A may be connected to the first cell plug 20A through a via 63A.

Second bit lines 53B may be disposed under the second stack 10B. The second bit lines 53B may extend in the second horizontal direction SD and be arranged in the first horizontal direction FD. The second bit line 53B may be connected to the second cell plug 20B through a via 63B.

Third bit lines 53C may be disposed under the third stack 10C. The third bit lines 53C may extend in the second horizontal direction SD and be arranged in the first horizontal direction FD. The third bit line 53C may be connected to the third cell plug 20C through a via 63C.

Fourth bit lines 53D may be disposed under the fourth stack 10D. The fourth bit lines 53D may extend in the second horizontal direction SD and be arranged in the first horizontal direction FD. The fourth bit line 53D may be connected to the fourth cell plug 20D through a via 63D.

Referring to FIG. 8 to FIG. 10, the extending direction of the first warpage prevention patterns 42A may be different from the extending direction of the second warpage prevention patterns 42B. The extending direction of the first warpage prevention patterns 42A may be different from the extending direction of the third warpage prevention patterns 42C. The extending direction of the fourth warpage prevention patterns 42D may be different from the extending direction of the second warpage prevention patterns 42B. The extending direction of the fourth warpage prevention patterns 42D may be different from the extending direction of the third warpage prevention patterns 42C.

The first warpage prevention patterns 42A and the fourth warpage prevention patterns 42D may extend in the first horizontal direction FD, and the second warpage prevention patterns 42B and the third warpage prevention patterns 42C may extend in the second horizontal direction SD. In FIG. 8 to FIG. 10, the extending direction of the first warpage prevention patterns 42A and the extending direction of the fourth warpage prevention patterns 42D are the same, but in other embodiments, the extending direction of the first warpage prevention patterns and the extending direction of the fourth warpage prevention patterns may be different from each other. In FIG. 8 to FIG. 10, the extending direction of the second warpage prevention patterns 42B and the extending direction of the third warpage prevention patterns 42C are the same, but in other embodiments the extending direction of the second warpage prevention patterns and the extending direction of the third warpage prevention patterns may be different from each other.

According to embodiments of the present disclosure, by configuring the extending directions of warpage prevention patterns disposed in neighboring plane regions to be different from each other, it is possible to suppress stress from being concentrated in one direction and suppress occurrence of warpage due to stress concentration.

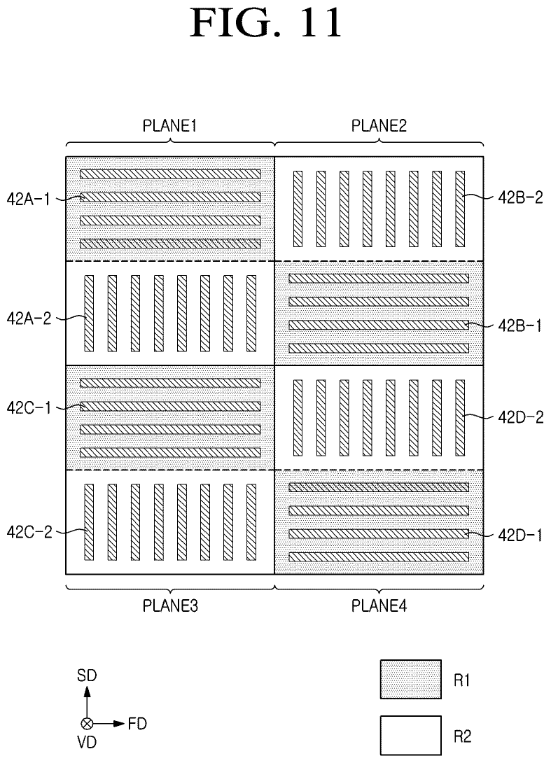

FIG. 11 to FIG. 13 are plan views schematically illustrating warpage prevention patterns of memory devices according to embodiments of the present disclosure.

Referring to FIG. 11, each of first, second, third and fourth plane regions PLANE1, PLANE2, PLANE3 PLANE4 has a first region R1 and a second region R2 that neighbor each other in the second horizontal direction SD.

The first region R1 of the first plane region PLANE1 and the second region R2 of the second plane region PLANE2 may be adjacent to each other in the first horizontal direction FD, and the second region R2 of the first plane region PLANE1 and the first region R1 of the second plane region PLANE2 may be adjacent to each other in the first horizontal direction FD.

The second region R2 of the first plane region PLANE1 and the first region R1 of the third plane region PLANE3 may be adjacent to each other in the second horizontal direction SD, and the first region R1 of the second plane region PLANE2 and the second region R2 of the fourth plane region PLANE4 may be adjacent to each other in the second horizontal direction SD.

The first region R1 of the third plane region PLANE3 and the second region R2 of the fourth plane region PLANE4 may neighbor each other in the first horizontal direction FD, and the second region R2 of the third plane region PLANE3 and the first region R1 of the fourth plane region PLANE4 may neighbor each other in the first horizontal direction FD.

The extending direction of first, second, third and fourth warpage prevention patterns 42A-1, 42B-1, 42C-1 and 42D-1 disposed in the first regions R1 of the first, second, third and fourth plane regions PLANE1, PLANE2, PLANE3 and PLANE4 and the extending direction of first, second, third and fourth warpage prevention patterns 42A-2, 42B-2, 42C-2 and 42D-2 disposed in the second regions R2 of the first, second, third and fourth plane regions PLANE1, PLANE2, PLANE3 and PLANE4 may be different from each other.

For example, the first, second, third and fourth warpage prevention patterns 42A-1, 42B-1, 42C-1 and 42D-1 disposed in the first regions R1 of the first, second, third and fourth plane regions PLANE1, PLANE2, PLANE3 and PLANE4 may extend in the first horizontal direction FD, and the first, second, third and fourth warpage prevention patterns 42A-2, 42B-2, 42C-2 and 42D-2 disposed in the second regions R2 of the first, second, third and fourth plane regions PLANE1, PLANE2, PLANE3 and PLANE4 may extend in the second horizontal direction SD.

In FIG. 11, each of the first, second, third and fourth plane regions PLANE1, PLANE2, PLANE3 and PLANE4 only has one first region R1 and one second region R2 that are arranged in the second horizontal direction SD, but in other embodiments each of the first, second, third and fourth plane regions PLANE1, PLANE2, PLANE3 and PLANE4 may have a plurality of first regions and a plurality of second regions that are alternately disposed in the second horizontal direction SD.

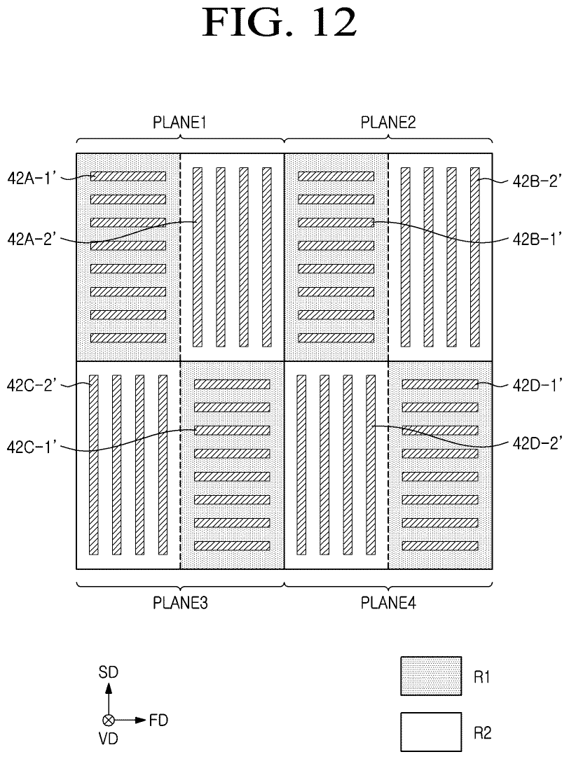

Referring to FIG. 12, each of first, second, third and fourth plane regions PLANE1, PLANE2, PLANE3 and PLANE4 has a first region R1 and a second region R2 that are adjacent to each other in the first horizontal direction FD.

The second region R2 of the first plane region PLANE1 and the first region R1 of the second plane region PLANE2 may be adjacent to each other in the first horizontal direction FD, and the first region R1 of the third plane region PLANE3 and the second region R2 of the fourth plane region PLANE4 may be adjacent to each other in the first horizontal direction FD.

The first region R1 of the first plane region PLANE1 and the second region R2 of the third plane region PLANE3 may neighbor each other in the second horizontal direction SD, and the second region R2 of the first plane region PLANE1 and the first region R1 of the third plane region PLANE3 may neighbor each other in the second horizontal direction SD.

The first region R1 of the second plane region PLANE2 and the second region R2 of the fourth plane region PLANE4 may neighbor each other in the second horizontal direction SD, and the second region R2 of the second plane region PLANE2 and the first region R1 of the fourth plane region PLANE4 may neighbor each other in the second horizontal direction SD.

The extending direction of first, second, third and fourth warpage prevention patterns 42A-1′, 42B-1′, 42C-1′ and 42D-1′ disposed in the first regions R1 of the first, second, third and fourth plane regions PLANE1, PLANE2, PLANE3 and PLANE4 and the extending direction of first, second, third and fourth warpage prevention patterns 42A-2′, 42B-2′, 42C-2′ and 42D-2′ disposed in the second regions R2 of the first, second, third and fourth plane regions PLANE1, PLANE2, PLANE3 and PLANE4 may be different from each other.

For example, the first, second, third and fourth warpage prevention patterns 42A-1′, 42B-1′, 42C-1′ and 42D-1′ disposed in the first regions R1 of the first, second, third and fourth plane regions PLANE1, PLANE2, PLANE3 and PLANE4 may extend in the first horizontal direction FD, and the first, second, third and fourth warpage prevention patterns 42A-2′, 42B-2′, 42C-2′ and 42D-2′ disposed in the second regions R2 of the first, second, third and fourth plane regions PLANE1, PLANE2, PLANE3 and PLANE4 may extend in the second horizontal direction SD.

In FIG. 12, each of the first, second, third and fourth plane regions PLANE1, PLANE2, PLANE3 and PLANE4 only has one first region R1 and one second region R2 that are disposed in the first horizontal direction FD, but in other embodiments, each of the first, second, third and fourth plane regions may have a plurality of first regions and a plurality of second regions that are alternately disposed in the first horizontal direction.

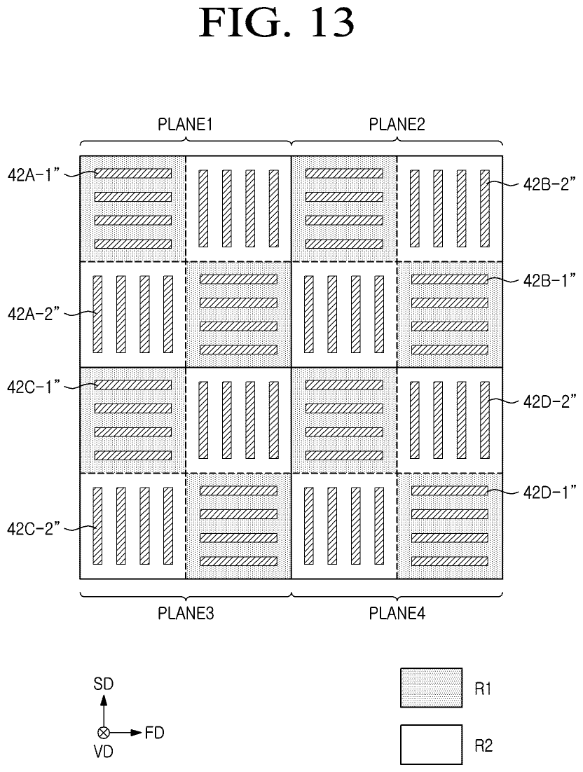

Referring to FIG. 13, each of first, second, third and fourth plane regions PLANE1, PLANE2, PLANE3 and PLANE4 has two first regions R1 and two second regions R2 that are disposed in the first horizontal direction FD and the second horizontal direction SD.

At the boundaries between plane regions, a first region R1 of any one of the first, second, third and fourth plane regions PLANE1, PLANE2, PLANE3 and PLANE4 may neighbor a second region R2 of another neighboring plane region.

The extending direction of first, second, third and fourth warpage prevention patterns 42A-1″, 42B-1″, 42C-1″ and 42D-1″ disposed in the first regions R1 of the first, second, third and fourth plane regions PLANE1, PLANE2, PLANE3 and PLANE4 and the extending direction of first, second, third and fourth warpage prevention patterns 42A-2″, 42B-2″, 42C-2″ and 42D-2″ disposed in the second regions R2 of the first, second, third and fourth plane regions PLANE1, PLANE2, PLANE3 and PLANE4 may be different from each other.

For example, the first, second, third and fourth warpage prevention patterns 42A-1″, 42B-1″, 42C-1″ and 42D-1″ disposed in the first regions R1 of the first, second, third and fourth plane regions PLANE1, PLANE2, PLANE3 and PLANE4 may extend in the first horizontal direction FD, and the first, second, third and fourth warpage prevention patterns 42A-2″, 42B-2″, 42C-2″ and 42D-2″ disposed in the second regions R2 of the first, second, third and fourth plane regions PLANE1, PLANE2, PLANE3 and PLANE4 may extend in the second horizontal direction SD.

In FIG. 13, each of the first, second, third and fourth plane regions PLANE1, PLANE2, PLANE3 and PLANE4 only has two first regions R1 and two second regions R2 that are disposed in the first horizontal direction FD and the second horizontal direction SD, but in other embodiments, each of the first, second, third and fourth plane regions may have a plurality of first regions and a plurality of second regions that are alternately disposed in the first horizontal direction and the second horizontal direction to form a checkerboard pattern.

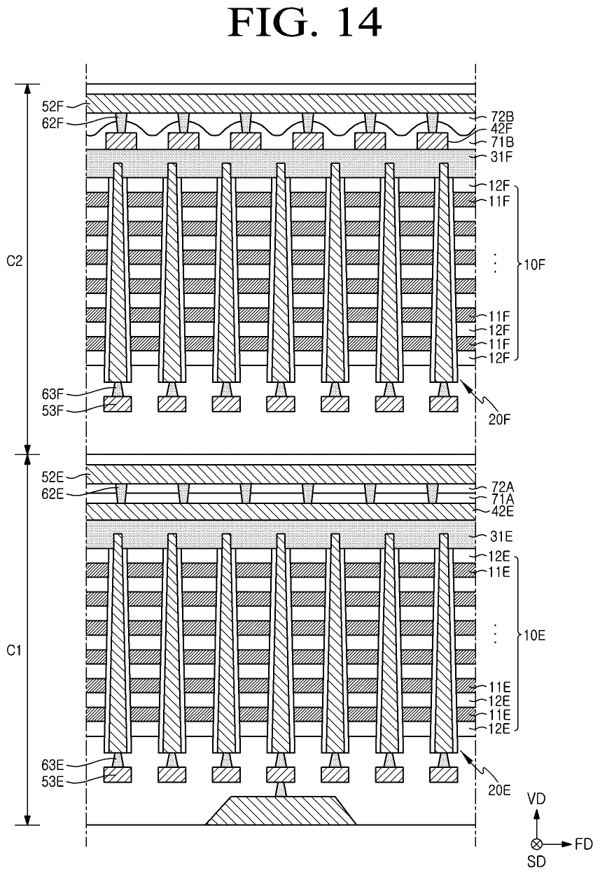

FIG. 14 is a cross-sectional view of a memory device according to an embodiment of the present disclosure.

Referring to FIG. 14, a memory device according to an embodiment of the present disclosure may include a lower structure C1 and an upper structure C2 that is disposed on the lower structure C1.

The lower structure C1 may include a lower stack 10E, a lower cell plug 20E, a lower source plate 31E and lower warpage prevention patterns 42E.

The lower stack 10E may include a plurality of lower electrode layers 11E and a plurality of lower interlayer insulating layers 12E that are alternately stacked in the vertical direction VD.

A plurality of lower cell plugs 20E may penetrate the lower stack 10E in the vertical direction VD. A plurality of lower cell strings corresponding to the plurality of lower cell plugs 20E may be defined. The plurality of lower cell strings may constitute a lower memory cell array.

The lower source plate 31E may be disposed on the lower stack 10E. The lower source plate 31E may be connected to upper ends of the lower cell plugs 20E.

The lower warpage prevention patterns 42E may be disposed on the lower source plate 31E. The lower warpage prevention patterns 42E may be provided to disperse or alleviate stress so as to suppress warpage. The lower warpage prevention patterns 42E may have a hardness greater than the hardness of the lower source plate 31E.

The lower warpage prevention patterns 42E may be connected to the lower source plate 31E. The lower warpage prevention patterns 42E may contact the upper surface of the lower source plate 31E. The lower warpage prevention patterns 42E may be formed of a conductive material with a lower resistivity than the lower source plate 31E. The lower source plate 31E may include polysilicon, and the lower warpage prevention patterns 42E may include metal. The lower warpage prevention patterns 42E may transmit a source voltage to the lower source plate 31E.

A first lower insulating layer 71A may be disposed on the lower source plate 31E to cover the lower warpage prevention patterns 42E. The first lower insulating layer 71A may have protrusions corresponding to the lower warpage prevention patterns 42E on the upper surface thereof.

A second lower insulating layer 72A may be disposed on the first lower insulating layer 71A, and a lower source line 52E may be disposed on the second lower insulating layer 72A.

The lower source line 52E may be connected to the lower warpage prevention patterns 42E through a plurality of vias 62E. The lower source line 52E may be connected to the lower source plate 31E through the vias 62E and the lower warpage prevention patterns 42E. The source voltage loaded onto the lower source line 52E may be transmitted to the lower source plate 31E through the vias 62E and the lower warpage prevention patterns 42E.

Lower bit lines 53E may be disposed under the lower stack 10E. The lower bit lines 53E may extend in the second horizontal direction SD and be arranged in the first horizontal direction FD. A lower bit line 53E may be connected to a lower cell plug 20E through a via 63E.

The upper structure C2 may be bonded onto the lower structure C1. The upper structure C2 may include an upper stack 10F, an upper cell plug 20F, an upper source plate 31F and upper warpage prevention patterns 42F.

The upper stack 10F may include a plurality of upper electrode layers 11F and a plurality of upper interlayer insulating layers 12F that are alternately stacked in the vertical direction VD. The upper electrode layers 11F and the upper interlayer insulating layers 12F may extend in the first horizontal direction FD.

A plurality of upper cell plugs 20F may penetrate the upper stack 10F in the vertical direction VD. A plurality of upper cell strings corresponding to the plurality of upper cell plugs 20F may be defined. The plurality of upper cell strings may constitute an upper memory cell array.

The upper source plate 31F may be disposed on the upper stack 10F. The upper source plate 31F may be connected to the upper ends of the upper cell plugs 20F.

The upper warpage prevention patterns 42F may be disposed on the upper source plate 31F. The upper warpage prevention patterns 42F may be provided to disperse or alleviate stress so as to suppress warpage. The upper warpage prevention patterns 42F may have a hardness greater than the hardness of the upper source plate 31F.

The upper warpage prevention patterns 42F may be connected to the upper source plate 31F. The upper warpage prevention patterns 42F may contact the upper surface of the upper source plate 31F. The upper warpage prevention patterns 42F may be formed of a conductive material with a lower resistivity than the upper source plate 31F. The upper source plate 31F may include polysilicon, and the upper warpage prevention patterns 42F may include metal.

The extending direction of the upper warpage prevention patterns 42F may be different from the extending direction of the lower warpage prevention patterns 42E. For example, the lower warpage prevention patterns 42E may extend in the first horizontal direction FD, and the upper warpage prevention patterns 42F may extend in the second horizontal direction SD.

A first upper insulating layer 71B may be disposed on the upper source plate 31F to cover the upper warpage prevention patterns 42F. The first upper insulating layer 71B may have protrusions corresponding to the upper warpage prevention patterns 42F on the upper surface thereof.

A second upper insulating layer 72B may be disposed on the first upper insulating layer 71B, and an upper source line 52F may be disposed on the second upper insulating layer 72B.

The upper source line 52F may be connected to the upper warpage prevention patterns 42F through a plurality of vias 62F. The upper source line 52F may be connected to the upper source plate 31F through the vias 62F and the upper warpage prevention patterns 42F. The source voltage loaded onto the upper source line 52F may be transmitted to the upper source plate 31F through the vias 62F and the upper warpage prevention patterns 42F.

Upper bit lines 53F may be disposed under the upper stack 10F. The upper bit lines 53F may extend in the second horizontal direction SD and be arranged in the first horizontal direction FD. An upper bit line 53F may be connected to an upper cell plug 20F through a via 63F.

The extending direction of the lower warpage prevention patterns 42E and the extending direction of the upper warpage prevention patterns 42F may be different from each other. For example, the lower warpage prevention patterns 42E may extend in the first horizontal direction FD, and the upper warpage prevention patterns 42F may extend in the second horizontal direction SD.

According to an embodiment of the present disclosure, by configuring the extending direction of the lower warpage prevention patterns 42E included in the lower structure C1 and the extending direction of the upper warpage prevention patterns 43F included in the upper structure C2 to be different from each other, it is possible to suppress stress from being concentrated in one direction and suppress occurrence of warpage by stress concentration.

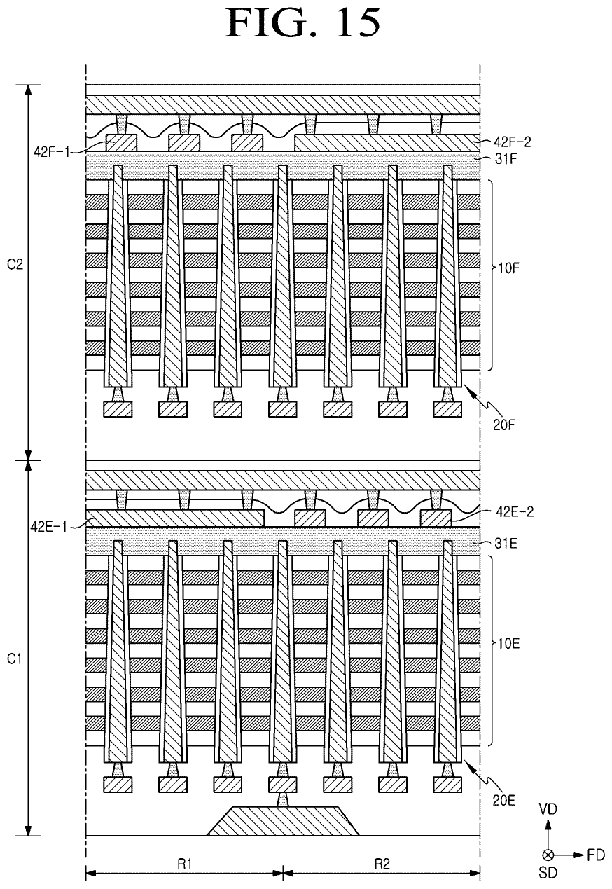

FIG. 15 is a cross-sectional view of a memory device according to an embodiment of the present disclosure.

Referring to FIG. 15, lower warpage prevention patterns 42E-1 and 42E-2 and upper warpage prevention patterns 42F-1 and 42F-2 may be disposed respectively in a first region R1 and a second region R2 that neighbors the first region R1.

The extending direction of the lower warpage prevention patterns 42E-1 disposed in the first region R1 and the extending direction of the lower warpage prevention patterns 42E-2 disposed in the second region R2 may be different from each other. The extending direction of the upper warpage prevention patterns 42F-1 disposed in the first region R1 and the extending direction of the upper warpage prevention patterns 42F-2 disposed in the second region R2 may be different from each other.

The extending direction of the lower warpage prevention patterns 42E-1 disposed in the first region R1 and the extending direction of the upper warpage prevention patterns 42F-1 disposed in the first region R1 may be different from each other. The extending direction of the lower warpage prevention patterns 42E-2 disposed in the second region R2 and the extending direction of the upper warpage prevention patterns 42F-2 disposed in the second region R2 may be different from each other. The lower warpage prevention patterns 42E-1 of the first region R1 and the upper warpage prevention patterns 42F-2 of the second region R2 may both extend in the first horizontal direction FD, and the lower warpage prevention patterns 42E-2 of the second region R2 and the upper warpage prevention patterns 42F-1 of the first region R1 may both extend in the second horizontal direction SD.

In FIG. 15, the extending direction of the lower warpage prevention patterns 42E-1 of the first region R1 and the extending direction of the upper warpage prevention patterns 42F-2 of the second region R2 are the same, but in other embodiments the extending direction of the lower warpage prevention patterns of the first region and the extending direction of the upper warpage prevention patterns of the second region may be different from each other. In FIG. 15, the extending direction of the lower warpage prevention patterns 42E-2 of the second region R2 and the extending direction of the upper warpage prevention patterns 42F-1 of the first region R1 are the same, but in other embodiments, the extending direction of the lower warpage prevention patterns of the second region and the extending direction of the upper warpage prevention patterns of the first region may be different from each other.

In FIG. 15, the first region R1 and the second region R2 neighbor each other in the first horizontal direction FD, but in other embodiments the first region and the second region may be arranged in a horizontal direction intersecting the first horizontal direction, such as for example, the second horizontal direction.

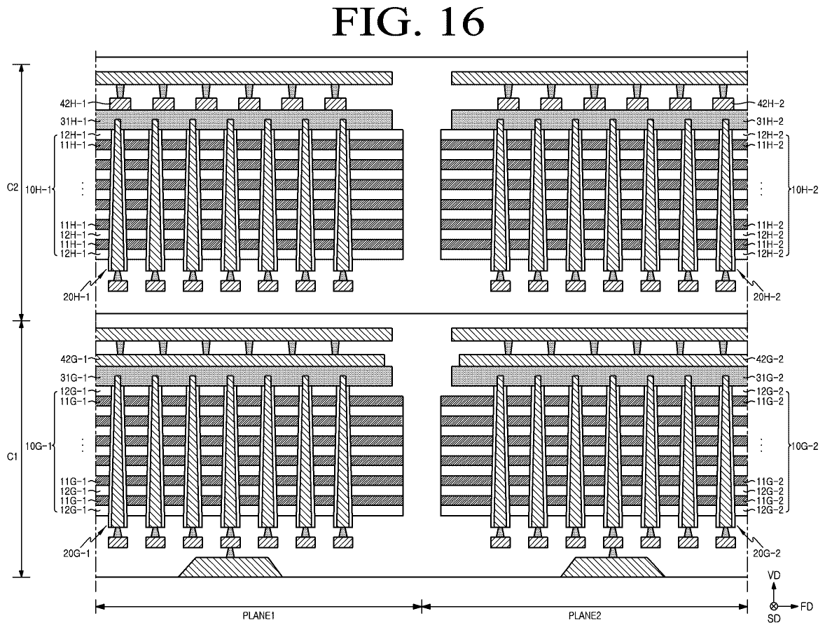

FIG. 16 is a cross-sectional view of a memory device according to an embodiment of the present disclosure.

Referring to FIG. 16, a memory device according to an embodiment of the present disclosure may include a first plane region PLANE1 and a second plane region PLANE2 that neighbors the first plane region PLANE1.

A lower structure C1 may include first and second lower stacks 10G-1 and 10G-2, first and second lower cell plugs 20G-1 and 20G-2, first and second lower source plates 31G-1 and 31G-2 and first and second lower warpage prevention patterns 42G-1 and 42G-2.

The first lower stack 10G-1 may be disposed in the first plane region PLANE1, and may include a plurality of first lower electrode layers 11G-1 and a plurality of first lower interlayer insulating layers 12G-1 that are alternately stacked in the vertical direction VD.

A plurality of first lower cell plugs 20G-1 may penetrate the first lower stack 10G-1 in the vertical direction VD. A plurality of first lower cell strings corresponding to the plurality of first lower cell plugs 20G-1 may be defined. The plurality of first lower cell strings may constitute a first lower memory cell array.

The first lower source plate 31G-1 may be disposed on the first lower stack 10G-1. The first lower source plate 31G-1 may be connected to the upper ends of the first lower cell plugs 20G-1.

The first lower warpage prevention patterns 42G-1 may be disposed on the first lower source plate 31G-1. The first lower warpage prevention patterns 42G-1 may be provided to disperse or alleviate stress so as to suppress warpage. The first lower warpage prevention patterns 42G-1 may have a hardness greater than the hardness of the first lower source plate 31G-1.

The first lower warpage prevention patterns 42G-1 may be connected to the first lower source plate 31G-1. The first lower warpage prevention patterns 42G-1 may contact the upper surface of the first lower source plate 31G-1. The first lower warpage prevention patterns 42G-1 may be formed of a conductive material with a lower resistivity than the first lower source plate 31G-1. The first lower source plate 31G-1 may include polysilicon, and the first lower warpage prevention patterns 42G-1 may include metal. The first lower warpage prevention patterns 42G-1 may transmit a source voltage to the first lower source plate 31G-1.

The second lower stack 10G-2 may be disposed in the second plane region PLANE2. The second lower stack 10G-2 may include a plurality of second lower electrode layers 11G-2 and a plurality of second lower interlayer insulating layers 12G-2 that are alternately stacked in the vertical direction VD.

A plurality of second lower cell plugs 20G-2 may penetrate the second lower stack 10G-2 in the vertical direction VD. A plurality of second lower cell strings corresponding to the plurality of second lower cell plugs 20G-2 may be defined. The plurality of second lower cell strings may constitute a second lower memory cell array.

The second lower source plate 31G-2 may be disposed on the second lower stack 10G-2. The second lower source plate 31G-2 may be connected to the upper ends of the second lower cell plugs 20G-2.

The second lower warpage prevention patterns 42G-2 may be disposed on the second lower source plate 31G-2. The second lower warpage prevention patterns 42G-2 may be provided to disperse or alleviate stress so as to suppress warpage. The second lower warpage prevention patterns 42G-2 may have a hardness greater than the hardness of the second lower source plate 31G-2.

The second lower warpage prevention patterns 42G-2 may be connected to the second lower source plate 31G-2. The second lower warpage prevention patterns 42G-2 may contact the upper surface of the second lower source plate 31G-2. The second lower warpage prevention patterns 42G-2 may be formed of a conductive material with a lower resistivity than the second lower source plate 31G-2. The second lower source plate 31G-2 may include polysilicon, and the second lower warpage prevention patterns 42G-2 may include metal. The second lower warpage prevention patterns 42G-2 may transmit a source voltage to the second lower source plate 31G-2.

An upper structure C2 may be bonded onto the lower structure C1. The upper structure C2 may include first and second upper stacks 10H-1 and 10H-2, first and second upper cell plugs 20H-1 and 20H-2, first and second upper source plates 31H-1 and 31H-2 and first and second upper warpage prevention patterns 42H-1 and 42H-2.

The first upper stack 10H-1 may be disposed in the first plane region PLANE1. The first upper stack 10H-1 may include a plurality of first upper electrode layers 11H-1 and a plurality of first upper interlayer insulating layers 12H-1 that are alternately stacked in the vertical direction VD.

A plurality of first upper cell plugs 20H-1 may penetrate the first upper stack 10H-1 in the vertical direction VD. A plurality of first upper cell strings corresponding to the plurality of first upper cell plugs 20H-1 may be defined. The plurality of first upper cell strings may constitute a first upper memory cell array.

The first upper source plate 31H-1 may be disposed on the first upper stack 10H-1. The first upper source plate 31H-1 may be connected to the upper ends of the first upper cell plugs 20H-1.

The first upper warpage prevention patterns 42H-1 may be disposed on the first upper source plate 31H-1. The first upper warpage prevention patterns 42H-1 may be provided to disperse or alleviate stress so as to suppress warpage. The first upper warpage prevention patterns 42H-1 may have a hardness greater than the hardness of the first upper source plate 31H-1.

The first upper warpage prevention patterns 42H-1 may be connected to the first upper source plate 31H-1. The first upper warpage prevention patterns 42H-1 may contact the upper surface of the first upper source plate 31H-1. The first upper warpage prevention patterns 42H-1 may be formed of a conductive material with a lower resistivity than the first upper source plate 31H-1. The first upper source plate 31H-1 may include polysilicon, and the first upper warpage prevention patterns 42H-1 may include metal. The first upper warpage prevention patterns 42H-1 may transmit a source voltage to the first upper source plate 31H-1.

The second upper stack 10H-2 may be disposed in the second plane region PLANE2. The second upper stack 10H-2 may include a plurality of second upper electrode layers 11H-2 and a plurality of second upper interlayer insulating layers 12H-2 that are alternately stacked in the vertical direction VD.

A plurality of second upper cell plugs 20H-2 may penetrate the second upper stack 10H-2 in the vertical direction VD. A plurality of second upper cell strings corresponding to the plurality of second upper cell plugs 20H-2 may be defined. The plurality of second upper cell strings may constitute a second upper memory cell array.

The second upper source plate 31H-2 may be disposed on the second upper stack 10H-2. The second upper source plate 31H-2 may be connected to the upper ends of the second upper cell plugs 20H-2.

The second upper warpage prevention patterns 42H-2 may be disposed on the second upper source plate 31H-2. The second upper warpage prevention patterns 42H-2 may be provided to disperse or alleviate stress so as to suppress warpage. The second upper warpage prevention patterns 42H-2 may have a hardness greater than the hardness of the second upper source plate 31H-2.

The second upper warpage prevention patterns 42H-2 may be connected to the second upper source plate 31H-2. The second upper warpage prevention patterns 42H-2 may contact the upper surface of the second upper source plate 31H-2. The second upper warpage prevention patterns 42H-2 may be formed of a conductive material with a lower resistivity than the second upper source plate 31H-2. The second upper source plate 31H-2 may include polysilicon, and the second upper warpage prevention patterns 42H-2 may include metal. The second upper warpage prevention patterns 42H-2 may transmit a source voltage to the second upper source plate 31H-2.

The extending direction of the first and second lower warpage prevention patterns 42G-1 and 42G-2 and the extending direction of the first and second upper warpage prevention patterns 42H-1 and 42H-2 may be different from each other. As illustrated in FIG. 16, the first and second lower warpage prevention patterns 42G-1 and 42G-2 may extend in the first horizontal direction FD, and the first and second upper warpage prevention patterns 42H-1 and 42H-2 may extend in the second horizontal direction SD. Accordingly, stress may be suppressed from being concentrated in one direction, and occurrence of warpage by stress concentration may be suppressed.

In FIG. 16, the first plane region PLANE1 and the second plane region PLANE2 neighbor each other in the first horizontal direction FD, but in other embodiments the first plane region and the second plane region may neighbor each other in a horizontal direction intersecting the first horizontal direction such as for example, the second horizontal direction.

In FIG. 16, the extending direction of the first lower warpage prevention patterns 42G-1 and the extending direction of the second lower warpage prevention patterns 42G-2 are the same, but in other embodiments, the extending direction of the first lower warpage prevention patterns and the extending direction of the second lower warpage prevention patterns may be different from each other. In FIG. 16, the extending direction of the first upper warpage prevention patterns 42H-1 and the extending direction of the second upper warpage prevention patterns 42H-2 are the same, but in other embodiments, the extending direction of the first upper warpage prevention patterns and the extending direction of the second upper warpage prevention patterns may be different from each other.

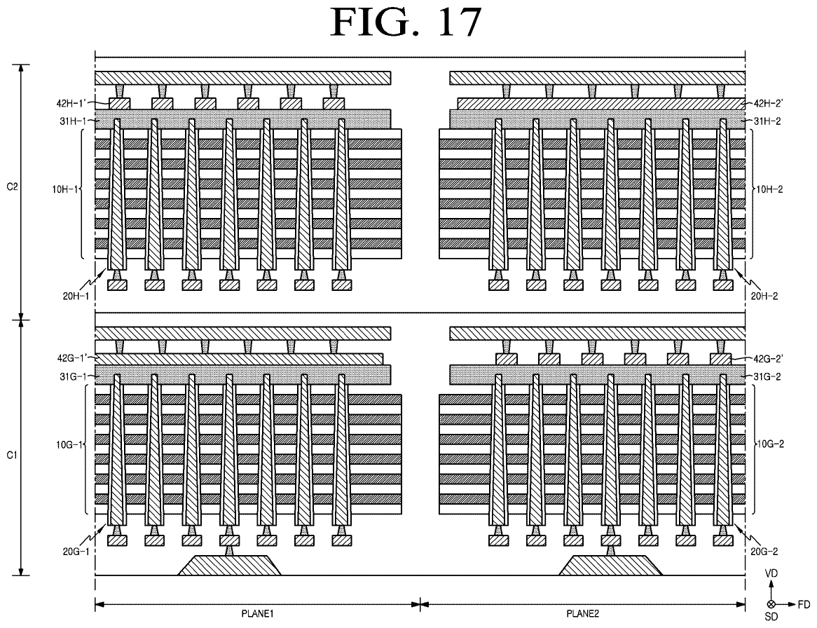

FIG. 17 is a cross-sectional view of a memory device according to an embodiment of the present disclosure.

Referring to FIG. 17, first lower warpage prevention patterns 42G-1′ may extend in the first horizontal direction FD, and second lower warpage prevention patterns 42G-2′ may extend in the second horizontal direction SD. First upper warpage prevention patterns 42H-1′ may extend in the second horizontal direction SD, and second upper warpage prevention patterns 42H-2′ may extend in the first horizontal direction FD.

In FIG. 17, the extending direction of the first lower warpage prevention patterns 42G-1′ and the extending direction of the second upper warpage prevention patterns 42H-2′ are the same, but in other embodiments, the extending direction of the first lower warpage prevention patterns and the extending direction of the second upper warpage prevention patterns may be different from each other. In FIG. 17, the extending direction of the first upper warpage prevention patterns 42H-1′ and the extending direction of the second lower warpage prevention patterns 42G-2′ are the same, but in other embodiments, the extending direction of the first upper warpage prevention patterns and the extending direction of the second lower warpage prevention patterns may be different from each other.

The above description has been presented to enable any person skilled in the art to make, use and practice the technical features of the present disclosure, and has been provided in the context of a particular application and its requirements as examples. Various modifications, additions and substitutions to the described embodiments will be readily apparent to those skilled in the art, and the principles described herein may be applied to other embodiments and applications without departing from the scope of the present disclosure. Therefore, the embodiments disclosed above and in the accompanying drawings should be considered in a descriptive sense only and not for limiting the technological scope. The technological scope of the present disclosure is not limited by the embodiments and the accompanying drawings.

What is claimed is:

1. A memory device comprising:
a stack including a plurality of electrode layers and a plurality of interlayer insulating layers that are alternately stacked in a vertical direction;
a source plate disposed on the stack; and
a plurality of warpage prevention patterns disposed on the source plate.

2. The memory device according to claim 1, wherein the plurality of warpage prevention patterns have a hardness greater than the hardness of the source plate.

3. The memory device according to claim 1, wherein the plurality of warpage prevention patterns are formed of a conductive material with a lower resistivity than the source plate.

4. The memory device according to claim 1, wherein the source plate includes polysilicon, and the plurality of warpage prevention patterns include metal.

5. The memory device according to claim 1, wherein
the plurality of warpage prevention patterns are disposed in a first region and a second region adjacent to the first region,
an extending direction of the plurality of warpage prevention patterns disposed in the first region and an extending direction of the plurality of warpage prevention patterns disposed in the second region are different from each other,
the plurality of warpage prevention patterns of the first region extend in a first horizontal direction, and
the plurality of warpage prevention patterns of the second region extend in a second horizontal direction perpendicular to the first horizontal direction.

6. The memory device according to claim 1, wherein
the plurality of warpage prevention patterns are disposed in a plurality of first regions and a plurality of second regions,
the plurality of first regions and the plurality of second regions are alternately disposed in a first horizontal direction and disposed in a second horizontal direction intersecting the first horizontal direction, and
an extending direction of the plurality of warpage prevention patterns disposed in the plurality of first regions and an extending direction of the plurality of warpage prevention patterns disposed in the plurality of second regions are different from each other.

7. A memory device comprising:
a first stack disposed in a first plane region, and including a plurality of first electrode layers and a plurality of first interlayer insulating layers that are alternately stacked in a vertical direction;
a second stack disposed in a second plane region, and including a plurality of second electrode layers and a plurality of second interlayer insulating layers that are alternately stacked in the vertical direction;
a first source plate disposed on the first stack;
a second source plate disposed on the second stack;
a plurality of first warpage prevention patterns disposed on the first source plate; and
a plurality of second warpage prevention patterns disposed on the second source plate.

8. The memory device according to claim 7, wherein an extending direction of the plurality of first warpage prevention patterns and an extending direction of the plurality of second warpage prevention patterns are different from each other.

9. The memory device according to claim 7, wherein
each of the first and second plane regions includes a first region and a second region adjacent to the first region,
an extending direction of the plurality of first warpage prevention patterns disposed in the first region and an extending direction of the plurality of first warpage prevention patterns disposed in the second region are different from each other, the first region of the first plane region and the second region of the second plane region neighbor each other, and
the second region of the first plane region and the first region of the second plane region neighbor each other.

10. The memory device according to claim 7, wherein
each of the first and second plane regions includes a plurality of first regions and a plurality of second regions that are alternately disposed in a first horizontal direction and a second horizontal direction intersecting the first horizontal direction, and
an extending direction of the plurality of first warpage prevention patterns disposed in the plurality of first regions and an extending direction of the plurality of first warpage prevention patterns disposed in the plurality of second regions are different from each other.

11. The memory device according to claim 7, wherein
the plurality of first warpage prevention patterns are connected to the first source plate,
the plurality of second warpage prevention patterns are connected to the second source plate, the plurality of first warpage prevention patterns contact an upper surface of the first source plate, and
the plurality of second warpage prevention patterns contact an upper surface of the second source plate.

12. The memory device according to claim 7, wherein
the plurality of first warpage prevention patterns have a hardness greater than the hardness of the first source plate, and
the plurality of second warpage prevention patterns have the hardness greater than the hardness of the second source plate.

13. The memory device according to claim 7, wherein
the plurality of first warpage prevention patterns are formed of a conductive material with a lower resistivity than the first source plate, and
the plurality of second warpage prevention patterns are formed of a conductive material with a lower resistivity than the second source plate.

14. The memory device according to claim 7, wherein the first and second source plates include polysilicon, and the plurality of first and second warpage prevention patterns include metal.

15. A memory device comprising:
a lower structure; and
an upper structure disposed on the lower structure,
wherein the lower structure comprises:
a lower stack including a plurality of lower electrode layers and a plurality of lower interlayer insulating layers that are alternately stacked in a vertical direction;
a lower source plate disposed on the lower stack; and
a plurality of lower warpage prevention patterns disposed on the lower source plate, and
wherein the upper structure comprises:
an upper stack including a plurality of upper electrode layers and a plurality of upper interlayer insulating layers that are alternately stacked in the vertical direction;
an upper source plate disposed on the upper stack; and
a plurality of upper warpage prevention patterns disposed on the upper source plate.

16. The memory device according to claim 15, wherein an extending direction of the plurality of lower warpage prevention patterns and an extending direction of the plurality of upper warpage prevention patterns are different from each other.

17. The memory device according to claim 15, wherein
the plurality of lower warpage prevention patterns and the plurality of upper warpage prevention patterns are disposed in a first region and a second region,
an extending direction of the plurality of lower warpage prevention patterns disposed in the first region and an extending direction of the plurality of upper warpage prevention patterns disposed in the first region are different from each other, and
an extending direction of the plurality of lower warpage prevention patterns disposed in the second region and an extending direction of the plurality of upper warpage prevention patterns disposed in the second region are different from each other.

18. The memory device according to claim 15, wherein
the plurality of lower warpage prevention patterns are connected to the lower source plate,
the plurality of upper warpage prevention patterns are connected to the upper source plate, the plurality of lower warpage prevention patterns contact an upper surface of the lower source plate, and
the plurality of upper warpage prevention patterns contact an upper surface of the upper source plate.

19. The memory device according to claim 15, wherein
the plurality of lower warpage prevention patterns are formed of a conductive material with a lower resistivity than the lower source plate, and
the plurality of upper warpage prevention patterns are formed of a conductive material with a lower resistivity than the upper source plate.

20. The memory device according to claim 15, wherein
the plurality of lower warpage prevention patterns have a hardness greater than the hardness of the lower source plate, and
the plurality of upper warpage prevention patterns have the hardness greater than the hardness of the upper source plate.
